(19) United States
(12) Patent Application Publication
(10) Pub. No.: US 2014/0365837 A1
(43) Pub. Date: Dec. 11, 2014

(54) TEST APPARATUS AND METHOD FOR TESTING SERVER

(71) Applicants: HONG FU JIN PRECISION INDUSTRY (ShenZhen) CO., LTD, Shenzhen (CN); HON HAI PRECISION INDUSTRY CO., LTD., New Taipei (TW)

(72) Inventor: GUANG-JIAN WANG, Shenzhen (CN)

(21) Appl. No.: 14/297,858

(22) Filed: Jun. 6, 2014

(30) Foreign Application Priority Data
Jun. 6, 2013 (CN) 201310222082X

(51) Int. Cl. G06F 11/22; G11C 29/56

(52) U.S. Cl. CPC G06F 11/2236; G11C 29/56012
USPC 714/722

(57) ABSTRACT

A test apparatus and method for testing a server are provided. The server includes a CPU group and a memory module. The test apparatus is electrically coupled to the CPU group and the memory module. The CPU group includes a number of CPUs, where each CPU is coupled to other CPUs through a plurality of QPI buses. The test apparatus includes a first copying control unit, a second copying control unit and a calculation unit. The first copying control unit controls each CPU to copy data stored in the memory module to a cache of the CPU and records the copying time duration. The second copying control unit controls each CPU to copy data stored in the memory module to caches of other CPUs and records the copying time duration. The calculation unit obtains copying speed according to the copying time duration.

### CROSS-REFERENCE TO RELATED APPLICATIONS

This application claims priority to Chinese Patent Application No. 201310222082.X filed on Jun. 6, 2013 in the China Intellectual Property Office, the contents of which are incorporated by reference herein.

### FIELD

The present disclosure relates to test apparatuses and test methods and especially relates to a test apparatus and a test method thereof for testing QuickPath Interconnect (QPI) buses of a server.

### BACKGROUND

A server usually includes two or more central processing units (CPUs), and the CPUs can communicate with each other by QPI buses. The QPI buses can couple the CPUs to each other and allow the CPUs to communicate with each other directly.

### BRIEF DESCRIPTION OF THE DRAWINGS

The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is a block diagram of an embodiment of a test apparatus of a server.

FIG. 2 is a part of a flowchart of an embodiment of an example method for testing a server.

FIG. 3 is another part of the flowchart of an embodiment of an example method for testing a server.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The present disclosure is described in relation to a test apparatus and method for testing a server. The server includes a CPU group and a memory module. The test apparatus is electrically coupled to the CPU group and the memory module. The CPU group includes a number of CPUs, where each CPU is coupled to other CPUs through a plurality of QPI buses. The test apparatus includes a first copying control unit, a second copying control unit and a calculation unit. The first copying control unit controls each CPU to copy data stored in the memory module to a cache of the CPU and records the copying time duration. The second copying control unit controls each CPU to copy data stored in the memory module to caches of other CPUs and records the copying time duration. The calculation unit obtains copying speed according to the copying time duration.

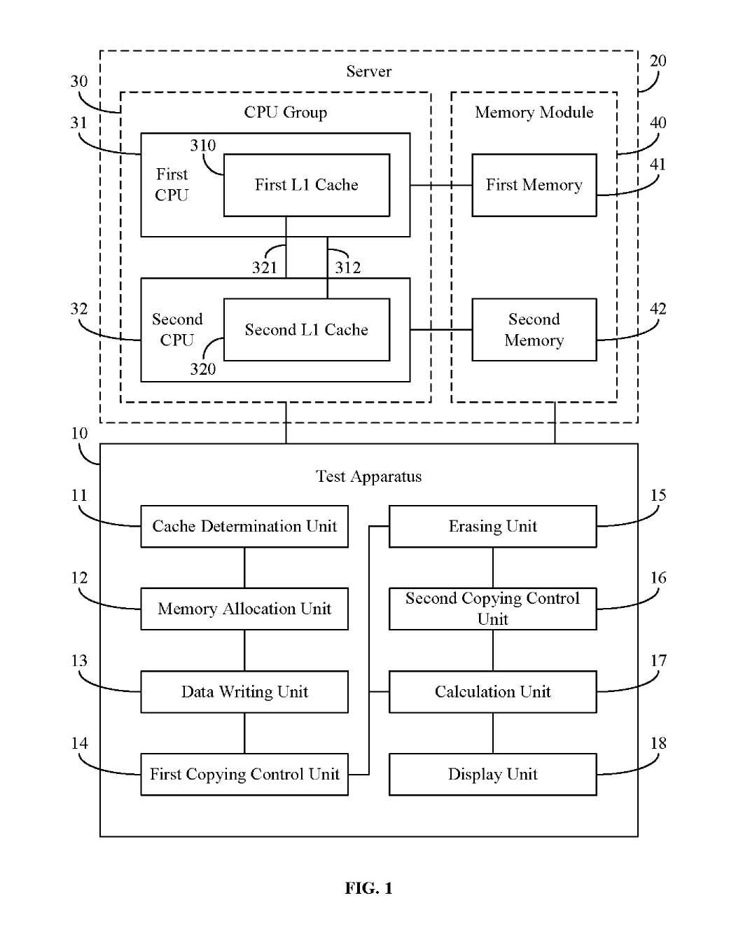

FIG. 1 illustrates an embodiment of a test apparatus 10 for testing a server 20. The server 20 can include a CPU group 30 and a memory module 40. The test apparatus 10 is electrically coupled to the CPU group 30 and the memory module 40. The CPU group 30 can include at least two CPUs. Each CPU includes a level 1 on-die cache (L1 cache). Data can be stored in the L1 cache. In at least one embodiment, the CPU group 30 can include a first CPU 31 and a second CPU 32. The first CPU 31 can include a first L1 cache 310, and the second CPU 32 can include a second L1 cache 320. The first CPU 31 and the second CPU 32 are coupled to each other through a first bus 312 and a second bus 321.

The test apparatus 10 can include a cache determination unit 11, a memory allocation unit 12, a data writing unit 13, a first copying control unit 14, an erasing unit 15, a second copying control unit 16, a calculation unit 17, and a display unit 18.

The cache determination unit 11 sends a first request to the first CPU 31 for confirming a capacity of the first L1 cache 310, and sends a second request to the second CPU 32 for confirming a capacity of the second L1 cache 320. The cache determination unit 11 obtains responses sent from the first CPU 31 and the second CPU 32, and further obtains the capacities of the first L1 cache 310 and the second L1 cache 320. In at least one embodiment, the capacity of the first L1 cache 310 is equal to the capacity of the second L1 cache 320.

The memory allocation unit 12 divides the memory module 40 into a plurality of memories, such as a first memory 41 and a second memory 42. The first memory 41 has a capacity substantially equal to the capacity of the first L1 cache 310, and the second memory 42 has a capacity substantially equal to the capacity of the second L1 cache 320. Thus, capacities of the first L1 cache 310, second L1 cache 320, first memory 41, and second memory 42 are the same.

The data writing unit 13 copies first random data (hereafter “first data”) into the first memory 41, and copies second random data (hereafter “second data”) into the second memory 42. In at least one embodiment, the first data has a size to fully occupy the capacity of first memory 41, and the second data has a size to fully occupy the capacity of the second memory 42.

The first copying control unit 14 sends a first copying command to the first CPU 31 for copying the second data of the second memory 42 to the first L1 cache 310. In detail, in response to receiving the first copying command, the first CPU 31 first copies the second data stored in the second memory 42 to the second L1 cache 320 of the second CPU 32. Then, the first CPU 31 copies the second data of the second L1 cache 320 to the first L1 cache 310 of the first CPU 31 through the first bus 312. The first copying control unit 14 records a first copying time duration of the first CPU 31 copying the second data from the second L1 cache 320 to the first L1 cache 310, and sends the first copying time duration to the calculation unit 17.

After the first CPU 31 completely copies the second data from the second memory 42 to the first L1 cache 310, the erasing unit 15 erases the second data from the first L1 cache 310, and further erases the second data from the second L1 cache 320.

The first copying control unit 14 sends a second copying command to the second CPU 32 for copying the first data of the first memory 41 to the second L1 cache 320. In detail, in response to receiving the second copying command, the second CPU 32 first copies the first data stored in the first memory 41 to the first L1 cache 310. Then, the second CPU 32 copies the first data of the first L1 cache 310 to the second L1 cache 320 of the second CPU 32 through the second bus 321. The first copying control unit 14 records a second copying time duration of the second CPU 32 copying the first data from the first L1 cache 310 to the second L1 cache 320, and sends the second copying time duration to the calculation unit 17.

After the first CPU 31 completely copies the first data from the first memory 41 to the second L1 cache 320, the erasing unit 15 erases the first data from the first L1 cache 310, and further erases the first data from the second L1 cache 320.

The calculation unit 17 obtains a first copying speed according to the first copying time duration, and obtains a second copying speed according to the second copying time duration. Specifically, the calculation unit 17 divides the size of the second data by the first copying time duration to obtain the first copying speed of the first CPU 31, and divides the size of the first data by the second copying time duration to obtain the second copying speed of the first CPU 31.

The second copying control unit 16 sends a third copying command to the first CPU 31 for copying the first data of the first memory 41 to the second L1 cache 320. In detail, in response to receiving the third copying command, the first CPU 31 first copies the first data stored in the first memory 41 to the first L1 cache 310. Then, the first CPU 31 copies the first data of the first L1 cache 310 to the second L1 cache 320 of the second CPU 32 through the first bus 312. The second copying control unit 16 records a third copying time duration of the first CPU 31 copying the first data from the first L1 cache 310 to the second L1 cache 320 and sends the third copying time duration to the calculation unit 17. The calculation unit 17 obtains a third copying speed of the first CPU 31 according to the third copying time duration.

After the first CPU 31 completely copies the first data from the first memory 41 to the second L1 cache 320, the second copying control unit 16 sends a fourth copying command to the second CPU 32 for copying the second data of the second memory 42 to the first L1 cache 310. In detail, in response to receiving the fourth copying command, the second CPU 32 first copies the second data stored in the second memory 42 to the second L1 cache 320. Then, the second CPU 32 copies the second data of the second L1 cache 320 to the first L1 cache 310 of the first CPU 31 through the second bus 321. The second copying control unit 16 records a fourth copying time duration of the second CPU 32 copying the second data from the second L1 cache 320 to the first L1 cache 310 and sends the fourth copying time duration to the calculation unit 17. The calculation unit 17 obtains a fourth copying speed of the second CPU 32 according to the fourth copying time duration.

The display unit 18 displays the first copying speed and the second copying speed of the first CPU 31, and displays the third copying speed and the fourth copying speed of the second CPU 32.

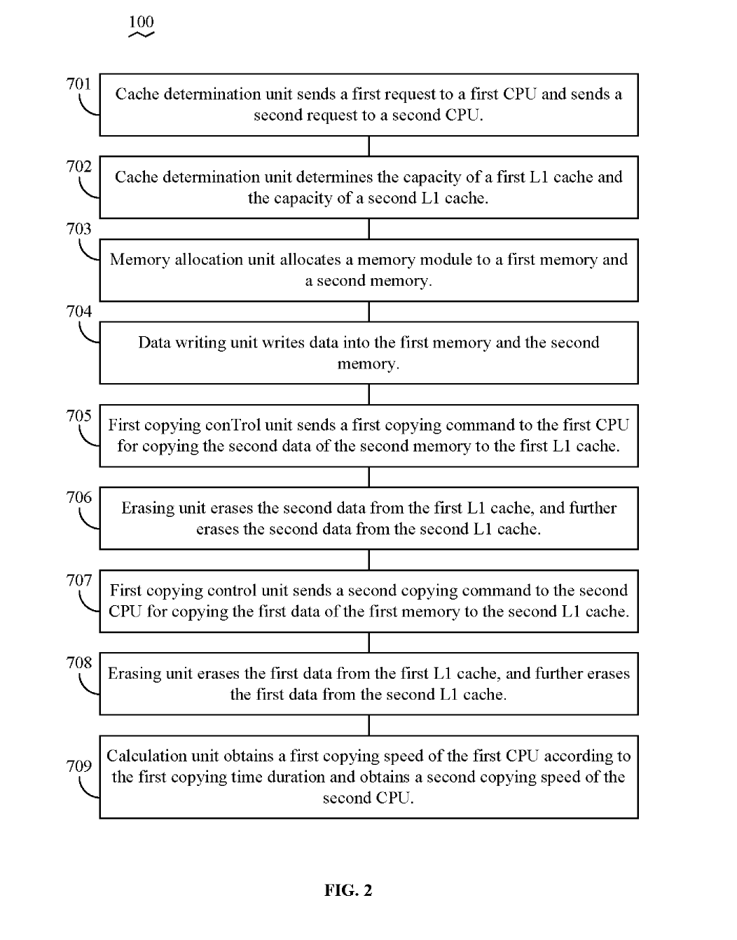

Referring to FIG. 2, a part of a flowchart of an embodiment of an example method 100 for a testing apparatus testing a server is presented. The example method 100 is provided by way of example, as there are a variety of ways to carry out the method. The example method 100 described below can be carried out using the configurations illustrated in FIG. 1 and various elements of these figures are referenced in explaining example method 100. Each block shown in FIG. 2 represents one or more processes, methods or subroutines, carried out in the exemplary method 100. Additionally, the illustrated order of blocks is by example only and the order of the blocks can be changed according to actual needs. The exemplary method 100 can begin at block 701.

At block 701, a cache determination unit sends a first request to a first CPU for confirming a capacity of a first L1 cache, and sends a second request to a second CPU for confirming a capacity of a second L1 cache.

At block 702, the cache determination unit obtains responses sent from the first CPU and the second CPU, and further obtains the capacities of the first L1 cache and the second L1 cache.

At block 703, a memory allocation unit divides a memory module into a first memory and a second memory. The first memory has a capacity substantially equal to the capacity of the first L1 cache, and the second memory has a capacity substantially equal to the capacity of the second L1 cache.

At block 704, a data writing unit writes first random data (hereinafter “first data”) into the first memory, and writes second random data (hereinafter “second data”) into the second memory.

At block 705, a first copying control unit sends a first copying command to the first CPU for copying the second data of the second memory to the first L1 cache. In response to receiving the first copying command, the first CPU first copies the second data stored in the second memory to the second L1 cache. Then, the first CPU copies the second data of the second L1 cache to the first L1 cache. The first copying control unit records a first copying time duration of the first CPU copying the second data from the second L1 cache to the first L1 cache and sends the first copying time duration to a calculation unit.

At block 706, an erasing unit erases the second data from the first L1 cache, and further erases the second data from the second L1 cache.

At block 707, the first copying control unit sends a second copying command to the second CPU for copying the first data of the first memory to the second L1 cache. In detail, in response to receiving the second copying command, the second CPU first copies the first data stored in the first memory to the first L1 cache. Then, the second CPU copies the first data of the first L1 cache to the second L1 cache of the second CPU through the second bus. The first copying control unit records a second copying time duration of the second CPU copying the first data from the first L1 cache to the second L1 cache, and sends the second copying time duration to the calculation unit.

At block 708, the erasing unit erases the first data from the first L1 cache, and further erases the first data from the second L1 cache.

At block 709, the calculation unit obtains a first copying speed of the first CPU according to the first copying time duration and obtains a second copying speed of the second CPU. Specifically, the calculation unit divides the size of the second data stored in the second memory by the first copying time duration of the first CPU toand obtains the first copying speed of the first CPU. The calculation unit and divides the size of the first data stored in the first memory by the second copying time duration of the second CPU and to obtains the second copying speed of the second CPU.

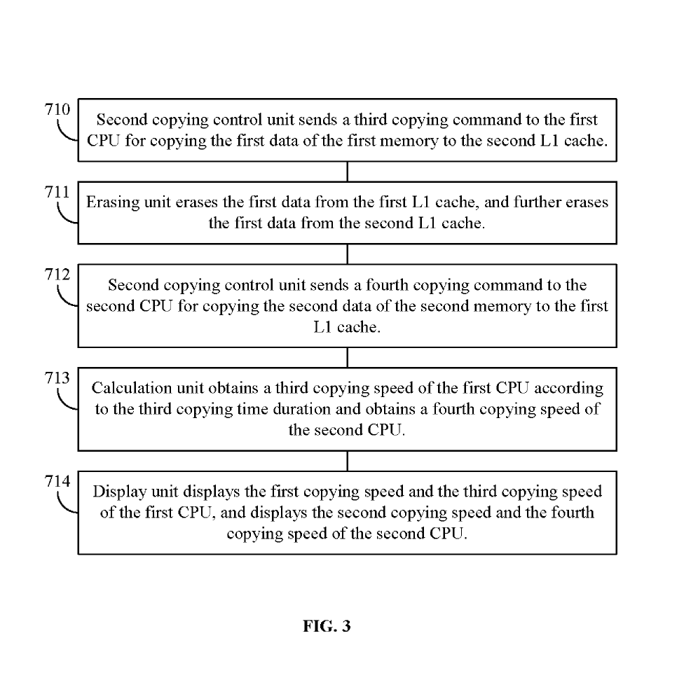

Referring to FIG. 3, another part of the flowchart of an embodiment of an example method 100 for a testing apparatus testing a server is presented.

At block 710, a second copying control unit sends a third copying command to the first CPU for copying the first data of the first memory to the second L1 cache. In detail, in response to receiving the third copying command, the first CPU first copies the first data stored in the first memory to the first L1 cache. Then, the first CPU copies the first data of the first L1 cache to the second L1 cache of the second CPU through the first bus. The second copying control unit records a third copying time duration of the first CPU copying the first data from the first L1 cache to the second L1 cache and sends the third copying time duration to the calculation unit.

At block 711, the erasing unit erases the first data from the first L1 cache, and further erases the first data from the second L1 cache.

At block 712, the second copying control unit sends a fourth copying command to the second CPU for copying the second data of the second memory to the first L1 cache. In detail, in response to receiving the fourth copying command, the second CPU first copies the second data stored in the second memory to the second L1 cache. Then, the second CPU copies the second data of the second L1 cache to the first L1 cache of the first CPU through the second bus. The second copying control unit records a fourth copying time duration of the second CPU copying the second data from the second L1 cache to the first L1 cache and sends the fourth copying time duration to the calculation unit.

At block 713, the calculation unit obtains a third copying speed of the first CPU according to the third copying time duration and obtains a fourth copying speed of the second CPU according to the fourth copying time duration. Specifically, the calculation unit divides the size of the first data stored in the first memory by the third copying time duration of the first CPU to obtain the third copying speed of the first CPU and divides the size of the second data stored in the second memory by the fourth copying time duration of the second CPU to obtain the fourth copying speed of the second CPU.

At block 714, a display unit displays the first copying speed and the third copying speed of the first CPU, and displays the second copying speed and the fourth copying speed of the second CPU.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A test apparatus for testing a server, the test apparatus comprising:
a first copying control unit configured to send a first copying command to a first CPU for copying second data to a first cache of the first CPU and record a first copying time duration of the first CPU;
a second copying control unit configured to send a second copying command to the first CPU for copying first data to a second cache of a second CPU and record a second copying time duration of the first CPU; and
a calculation unit configured to obtain a first copying speed of the first CPU according to the first copying time duration, and obtain a second copying speed of the first CPU according to the second copying time duration.

2. The test apparatus of claim 1, further comprising:
a memory allocation unit configured to divide a memory module to a plurality of memories comprising a second memory to store the second data;
wherein the first copying control unit sends the first copying command to the first CPU to trigger the first CPU to copy the second data stored in the second memory to the second cache of the second CPU, and further copy the second data from the second cache of the second CPU to the first cache of the first CPU, and records a time spent to copy the second data from the second cache of the second CPU to the first cache of the first CPU as the first copying time duration.

3. The test apparatus of claim 1, further comprising:
a memory allocation unit configured to divide a memory module to a plurality of memories comprising a first memory to store the first data;
wherein the second copying control unit sends the second copying command to the first CPU to trigger the first CPU to copy the first data from the first memory to the first cache of the first CPU, and further copy the first data from the first cache of the first CPU to the second cache of the second CPU, and records a time spent to copy the first data from the first cache of the first CPU to the second cache of the second CPU as the second copying time duration.

4. The test apparatus of claim 1, wherein the calculation unit is to obtain the first copying speed by dividing the size of the second data by the first copying time duration of the first CPU and obtain the second copying speed by dividing the size of the first data by the second copying time duration of the first CPU.

5. A test method for testing a server comprising a plurality of CPUs, the test method comprising:
sending a first copying command to a first CPU for copying second data to a first cache of the first CPU;
recording a first copying time duration of the first CPU;
sending a second copying command to the first CPU for copying first data to a second cache of a second CPU ;
recording a second copying time duration of the first CPU; and
obtaining a first copying speed of the first CPU according to the first copying time duration and a second copying speed of the first CPU according to the second copying time duration.

6. The test method of claim 5, further comprising:
dividing a memory module to a plurality of memories comprising a second memory to store the second data;
wherein the first copying command sent to the first CPU for triggering the first CPU to copy the second data stored in the second memory to the second cache of the second CPU, and further copy the second data from the second cache of the second CPU to the first cache of the first CPU, and records a time spent to copy the second data from the second cache of the second CPU to the first cache of the first CPU as the first copying time duration.

7. The test method of claim 5, further comprising:
dividing a memory module to a plurality of memories comprising a first memory to store the first data;
wherein the second copying command sent to the first CPU for triggering the first CPU to copy the first data from the first memory to the first cache of the first CPU, and further copy the first data from the first cache of the first CPU to the second cache of the second CPU, and records a time spent to copy the first data from the first cache of the first CPU to the second cache of the second CPU as the second copying time duration.
